(19) United States
(12) Patent Application Publication
(10) Pub. No.: US 2004/0194992 A1
(43) Pub. Date: Oct. 7, 2004

(54) Method for removing an image sensor from a printed circuit board

(76) Inventor: Dennis Pai, Hsinchu Hsien (TW)

Correspondence Address: PRO-TECHTOR INTERNATIONAL, 20775 Norada Court, Saratoga, CA, 95070-3018, US

(21) Appl. No.: 10/617,439

(22) Filed: Apr. 7, 2003

(51) Int. Cl. H05K 5/06; H01L 23/28

(52) U.S. Cl. 174/52.2

(57) ABSTRACT

A method for removing an image sensor from a printed circuit board. The printed circuit board has a first surface and a second surface. The image sensor is welded to the first surface, and the method includes the steps of: supplying a hot air stream to the first surface of the printed circuit board so as to distribute the hot air stream over a periphery of the image sensor and to melt solder; and providing a heater to heat the second surface of the printed circuit board and to raise a temperature of the second surface of the printed circuit board.

### BACKGROUND OF THE INVENTION

1. Field of the Invention

The invention relates to a method for removing an image sensor from a printed circuit board, and in particular to a method for effectively removing solder and for separating an image sensor from a printed circuit board.

2. Description of the Related Art

A general sensor is used to sense signals, which may be optical or audio signals. The sensor of the invention is used to receive image signals or optical signals. After receiving the image signals, the sensor converts the image signals into electrical signals, which are then transmitted to a printed circuit board via a substrate.

Referring to FIG. 1, a conventional image sensor includes a substrate 10, a frame layer 18, a photosensitive chip 26, a plurality of wires 28, and a transparent layer 34. The substrate 10 has an upper surface 12 on which first terminals 15 are formed, and a lower surface 14 on which second terminals 16 are formed. The frame layer 18 has a first surface 20 and a second surface 22 adhered to the upper surface 12 of the substrate 10 to form a cavity 24 together with the substrate 10. The photosensitive chip 26 is arranged within the cavity 24 and is mounted to the upper surface 12 of the substrate 10. Each wire 28 has a first terminal 30 and a second terminal 32. The first terminals 30 are electrically connected to the photosensitive chip 26, and the second terminals 32 are electrically connected to the first terminals 15 of the substrate 10. The transparent layer 34 is adhered to the first surface 20 of the frame layer 18.

The second terminals 16 on the lower surface 14 of the substrate 10 are electrically connected to a printed circuit board 36 by solder 35. Then, the image sensor may be used in conjunction with electrical devices 38 (active devices, passive devices, and the like). However, when the image sensor is not precisely welded to the printed circuit board 36, the image sensor cannot be easily removed from the printed circuit board 36, and the printed circuit board 36 and the image sensor have to be treated as waste material. Thus, the manufacturing cost is relatively high.

### SUMMARY OF THE INVENTION

An object of the invention is to provide a method for effectively melting the solder and removing an image sensor from a printed circuit board.

To achieve the above-mentioned object, the invention provides a method for removing an image sensor from a printed circuit board. The printed circuit board has a first surface and a second surface. The image sensor is welded to the first surface, and the method includes the steps of: supplying a hot air stream to the first surface of the printed circuit board so as to distribute the hot air stream over a periphery of the image sensor and to melt solder; and providing a heater to heat the second surface of the printed circuit board and to raise a temperature of the second surface of the printed circuit board.

Consequently, the solder can be melted, the image sensor may be removed from the printed circuit board, and the image sensor and the printed circuit board may be reused.

### BRIEF DESCRIPTION OF THE DRAWINGS

FIG. 1 is a schematic illustration showing a conventional image sensor.

FIG. 2 is a first schematic illustration showing a method for removing an image sensor from a printed circuit board of the invention.

FIG. 3 is a second schematic illustration showing the method for removing the image sensor from the printed circuit board of the invention.

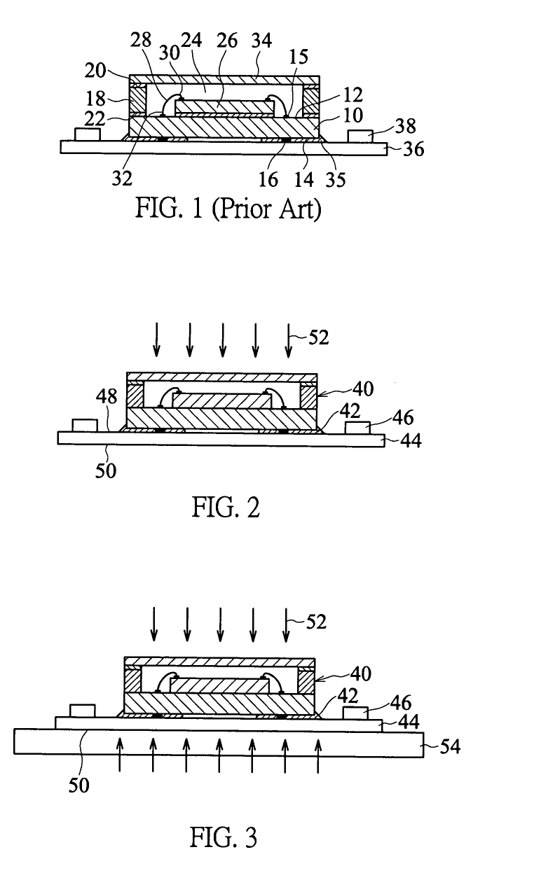

### DETAILED DESCRIPTION OF THE INVENTION

FIG. 2 is a first schematic illustration showing a method for removing an image sensor from a printed circuit board of the invention. An image sensor 40 is welded to a printed circuit board 44 by solder 42. A plurality of electrical devices (active devices or passive devices) 46 is mounted to the printed circuit board 44, which has a first surface 48 and a second surface 50. The image sensor 40 is welded to the first surface 48 of the printed circuit board 44. The method will be described in the following.

First, a hot air stream 52 is supplied to the first surface 48 of the printed circuit board 44 so that the hot air stream is distributed over a periphery of the image sensor 40 to melt the solder 42. The temperature of the hot air stream 52 may range from 170 to 190° C. to completely melt the solder 42.

Next, as shown in FIG. 3, a heater 54 is provided to heat the second surface 50 of the printed circuit board 44 and raise a temperature of the second surface 50 over 80° C. Therefore, it is possible to prevent the temperature difference between the first and second surfaces of the printed circuit board 44 from becoming too great, so that the printed circuit board 44 is free from distortion and deformation.

Consequently, raising the temperature of the printed circuit board 44 may melt the solder 42 and make it possible to remove the image sensor 40 from the printed circuit board 44. Then, the image sensor 40 and the printed circuit board 44 may be reused.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. A method for removing an image sensor from a printed circuit board, the printed circuit board having a first surface and a second surface, the image sensor being welded to the first surface, and the method comprising the steps of:
supplying a hot air stream to the first surface of the printed circuit board so as to distribute the hot air stream over a periphery of the image sensor and to melt solder; and
providing a heater to heat the second surface of the printed circuit board and to raise a temperature of the second surface of the printed circuit board.

2. The method according to claim 1, wherein a temperature of the hot air stream substantially ranges from 170 to 190° C.

3. The method according to claim 1, wherein the heater has a temperature substantially greater than 80° C.
